(19) United States
(12) Patent Application Publication
(10) Pub. No.: US 2015/0357491 A1
(43) Pub. Date: Dec. 10, 2015

(54) PHOTOELECTRIC CONVERSION ELEMENT

(71) Applicant: SHARP KABUSHIKI KAISHA, Osaka-shi (JP)

(72) Inventor: Kenji KIMOTO, Osaka-shi (JP)

(21) Appl. No.: 14/762,855

(22) PCT Filed: Mar. 27, 2014
(86) PCT No.: PCT/JP2014/058877

§ 371 Date: Jul. 23, 2015

(30) Foreign Application Priority Data
Mar. 28, 2013 (JP) 2013-069704

(51) Int. Cl. H01L 31/0224; H01L 31/075; H01L 31/0376

(52) U.S. Cl. CPC H01L 31/022441; H01L 31/03762; H01L 31/075

(57) ABSTRACT

A photoelectric conversion element includes a first lower electrode in contact with a first-conductivity-type layer and a first upper electrode disposed on the first lower electrode. A part of the first-conductivity-type layer and a part of a second-conductivity-type layer are located above a region where an intrinsic layer contacts an insulating layer.

### TECHNICAL FIELD

The present invention relates to photoelectric conversion elements.

### BACKGROUND ART

Solar cells that directly convert solar energy to electrical energy have been the subject of rapidly increasing expectations in recent years as next-generation energy sources from the global environmental viewpoint. Solar cells come in a wide variety of types including those that use compound semiconductors or organic materials. Currently, the mainstream solar cells are those which use silicon crystals.

Solar cells that are currently produced and sold in the largest quantity are those which have electrodes formed on a front surface, which is a surface on which the sunlight is incident, and electrodes formed on a back surface opposite the front surface.

However, forming electrodes on the front surface decreases the amount of incident sunlight by an amount corresponding to the area occupied by the electrodes that reflect and absorb the sunlight. Accordingly, development of solar cells in which electrodes are formed on back surfaces is in progress (for example, refer to Japanese Unexamined Patent Application Publication (Translation of PCT Application) No. 2009-524916 (PTL 1)).

FIG. 22 is a schematic cross-sectional view of an amorphous/crystalline silicon heterojunction device described in PTL 1. As illustrated in FIG. 22, in the amorphous/crystalline silicon heterojunction device described in PTL 1, an intrinsic hydrogenated amorphous silicon transition layer 102 is formed on a back surface of a crystalline silicon wafer 101, an n-doped region 103 and a p-doped region 104 of hydrogenated amorphous silicon are formed on the intrinsic hydrogenated amorphous silicon transition layer 102, electrodes 105 are formed on the n-doped region 103 and the p-doped region 104, and an insulating reflection layer 106 is formed between the electrodes 105.

In the amorphous/crystalline silicon heterojunction device described in PTL 1 illustrated in FIG. 22, the n-doped region 103 and the p-doped region 104 are formed by lithography and/or a shadow masking process (for example, refer to paragraph [0020] and the like of PTL 1).

### CITATION LIST

### Patent Literature

[PTL 1] Japanese Unexamined Patent Application Publication (Translation of PCT Application) No. 2009-524916

### SUMMARY OF INVENTION

### Technical Problem

In order to form an n-doped region 103 and a p-doped region 104 by lithography, the n-doped region 103 and the p-doped region 104 need to be etched by a process that can increase the etching selectivity ratios of the n-doped region 103 and the p-doped region 104 relative to the intrinsic hydrogenated amorphous silicon transition layer 102. However, PTL 1 is silent as to such an etching process that can increase the etching selectivity ratios.

Since the thickness of the laminate constituted by the intrinsic hydrogenated amorphous silicon transition layer 102 and the n-doped region 103 and the thickness of the laminate constituted by the intrinsic hydrogenated amorphous silicon transition layer 102 and the p-doped region 104 are few angstroms to several tens of nanometers (refer to paragraph [0018] of PTL 1), the thickness of the intrinsic hydrogenated amorphous silicon transition layer 102 is very small. It is extremely difficult to etch the n-doped region 103 and the p-doped region 104 while leaving such a thin intrinsic hydrogenated amorphous silicon transition layer 102 unetched.

In the case where an n-doped region 103 and a p-doped region 104 are formed by a shadow masking process, patterning accuracy is significantly degraded because during formation of the n-doped region 103 and the p-doped region 104 by a plasma CVD (chemical vapor deposition) method, gas reaching behind the mask renders it difficult to separate between the n-doped region 103 and the p-doped region 104; thus, the space between the n-doped region 103 and the p-doped region 104 needs to be large. However, widening the space between the n-doped region 103 and the p-doped region 104 increases the area that does not have the n-doped region 103 or the p-doped region 104, and thus decreases the conversion efficiency of the amorphous/crystalline silicon heterojunction device.

In addition, since the width of the p-doped region 104 is designed to be smaller than the width of the n-doped region 103, the n-doped region 103 is narrow. Accordingly, the parasitic resistance of the electrode 105 formed on the n-doped region 103 is high.

Since the electrode material used in the electrode 105 formed on the n-doped region 103 is the same as the electrode material used in the electrode 105 formed on the p-doped region 104, a material having an optimum work function cannot be used for each of the n-doped region 103 and the p-doped region 104, and thus the parasitic resistance of the electrode 105 tends to be high. Moreover, since light passes through the region between the electrodes 105, conversion efficiency is easily decreased.

Under the above-described circumstances, an object of the present invention is to provide a photoelectric conversion element that can be manufactured in high yield and has enhanced properties.

### Solution to Problem

The present invention provides a photoelectric conversion element that includes a semiconductor; an intrinsic layer disposed on the semiconductor and containing hydrogenated amorphous silicon; a first-conductivity-type layer of a first conductivity type that covers a part of the intrinsic layer; a second-conductivity-type layer of a second conductivity type that covers a part of the intrinsic layer; a first insulating layer that covers a part of the intrinsic layer; a first electrode disposed on the first-conductivity-type layer; and a second electrode disposed on the second-conductivity-type layer. The first electrode includes a first lower electrode in contact with the first-conductivity-type layer and a first upper electrode disposed on the first lower electrode. A part of the first-conductivity-type layer and a part of the second-conductivity-type layer are located above a region where the intrinsic layer contacts the insulating layer. According to this structure, patterning of the first-conductivity-type layer can be conducted over the insulating layer and damage on the semiconductor and the intrinsic layer inflicted during patterning of the first-conductivity-type layer can be decreased. Thus, a photoelectric conversion element can be manufactured in high yield and have enhanced properties.

### Advantageous Effects of Invention

According to the present invention, a photoelectric conversion element that can be manufactured in high yield and has enhanced properties can be provided.

### BRIEF DESCRIPTION OF DRAWINGS

FIG. 1 is a schematic cross-sectional view of a heterojunction-type back-contact cell of Embodiment 1.

FIG. 2 is a schematic cross-sectional view illustrating an example of a method for manufacturing the heterojunction-type back-contact cell of Embodiment 1.

FIG. 3 is a schematic cross-sectional view illustrating an example of a method for manufacturing the heterojunction-type back-contact cell of Embodiment 1.

FIG. 4 is a schematic cross-sectional view illustrating an example of a method for manufacturing the heterojunction-type back-contact cell of Embodiment 1.

FIG. 5 is a schematic cross-sectional view illustrating an example of a method for manufacturing the heterojunction-type back-contact cell of Embodiment 1.

FIG. 6 is a schematic cross-sectional view illustrating an example of a method for manufacturing the heterojunction-type back-contact cell of Embodiment 1.

FIG. 7 is a schematic cross-sectional view illustrating an example of a method for manufacturing the heterojunction-type back-contact cell of Embodiment 1.

FIG. 8 is a schematic cross-sectional view illustrating an example of a method for manufacturing the heterojunction-type back-contact cell of Embodiment 1.

FIG. 9 is a schematic cross-sectional view illustrating an example of a method for manufacturing the heterojunction-type back-contact cell of Embodiment 1.

FIG. 10 is a schematic cross-sectional view illustrating an example of a method for manufacturing the heterojunction-type back-contact cell of Embodiment 1.

FIG. 11 is a schematic cross-sectional view illustrating an example of a method for manufacturing the heterojunction-type back-contact cell of Embodiment 1.

FIG. 12 is a schematic cross-sectional view illustrating an example of a method for manufacturing the heterojunction-type back-contact cell of Embodiment 1.

FIG. 13 is a schematic cross-sectional view illustrating an example of a method for manufacturing the heterojunction-type back-contact cell of Embodiment 1.

FIG. 14 is a schematic cross-sectional view illustrating an example of a method for manufacturing the heterojunction-type back-contact cell of Embodiment 1.

FIG. 15 is a schematic cross-sectional view illustrating an example of a method for manufacturing the heterojunction-type back-contact cell of Embodiment 1.

FIG. 16 is a schematic cross-sectional view illustrating an example of a method for manufacturing the heterojunction-type back-contact cell of Embodiment 1.

FIG. 17 is a schematic cross-sectional view of a heterojunction-type back-contact cell of Embodiment 2.

FIG. 18 is a schematic cross-sectional view of a heterojunction-type back-contact cell of Embodiment 3.

FIG. 19(a) is a schematic cross-sectional view of a heterojunction-type back-contact cell of Example 1 and FIG. 19(b) is a schematic cross-sectional view taken along XIXb-XIXb in FIG. 19(a).

FIG. 20(a) is a schematic cross-sectional view of a heterojunction-type back-contact cell of Example 2 and FIG. 20(b) is a schematic cross-sectional view taken along XXb-XXb in FIG. 20(a).

FIG. 21(a) is a schematic cross-sectional view of a heterojunction-type back-contact cell of Example 3 and FIG. 21(b) is a schematic cross-sectional view taken along XXIb-XXIb in FIG. 21(a).

FIG. 22 is a schematic cross-sectional view of an amorphous/crystalline silicon heterojunction device described in PTL 1.

FIG. 23 is a schematic diagram of a structure of a photoelectric conversion module of Embodiment 4.

FIG. 24 is a schematic diagram of a structure of a solar power generation system of Embodiment 5.

FIG. 25 is a schematic diagram illustrating an example of a structure of the photoelectric conversion module array illustrated in FIG. 24.

FIG. 26 is a schematic diagram of a solar power generation system of Embodiment 6.

### DESCRIPTION OF EMBODIMENTS

Embodiments of the present invention will now be described. In the drawings illustrating the present invention, the same reference signs denote the same or corresponding parts.

### Embodiment 1

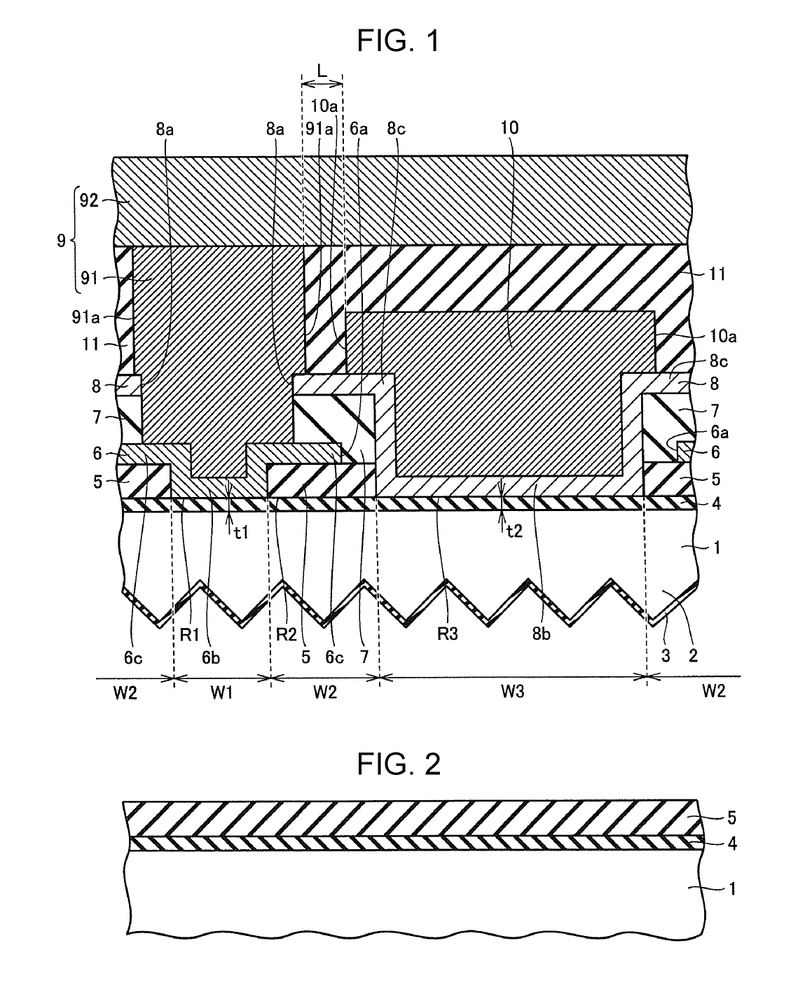

FIG. 1 is a schematic cross-sectional view of a heterojunction-type back-contact cell according to Embodiment 1 which is an example of a photoelectric conversion element according to the present invention. The heterojunction-type back-contact cell according to Embodiment 1 includes a semiconductor 1 composed of n-type single-crystal silicon, an intrinsic layer 4 that covers the entire back surface of the semiconductor 1 and contains i-type hydrogenated amorphous silicon, an n-type layer 6 that covers a part of the back surface of the intrinsic layer 4 and contains n-type hydrogenated amorphous silicon, a p-type layer 8 that covers a part of the back surface of the intrinsic layer 4 and contains p-type hydrogenated amorphous silicon, and a first insulating layer 5 that covers a part of the back surface of the intrinsic layer 4. The n-type layer 6, the p-type layer 8, and the first insulating layer 5 respectively cover different regions of the back surface of the semiconductor 1.

The first insulating layer 5 has a strip shape. The n-type layer 6 is formed to have a shape that has a groove portion 6b whose recess portion extends in a straight line in a direction normal to the plane of paper of FIG. 1, and a flap portion 6c that extends from upper edges of both side walls of the groove portion 6b toward outside of the groove portion 6b. The p-type layer 8 is formed into a shape that has a groove portion 8b whose recess portion extends in a straight line in the direction normal to the plane of paper of FIG. 1, and a flap portion 8c that extends from upper edges of both side walls of the groove portion 8b toward outside of the groove portion 8b.

A part of the back surface of the first insulating layer 5 is covered with the flap portion 6c which is an end region of the n-type layer 6. Another part of the back surface of the first insulating layer 5 is covered with a second insulating layer 7. A part of the back surface of the flap portion 6c of the n-type layer 6, is covered with the second insulating layer 7. The entire back surface of the second insulating layer 7 is covered with the flap portion 8c, which is an end region of the p-type layer 8.

A first lower electrode 91 fills the groove portion 6b of the n-type layer 6 and contacts the n-type layer 6 so as to cover a part of the back surface of the flap portion 6c. A second electrode 10 fills the groove portion 8b of the p-type layer 8 and contacts the p-type layer 8 so as to cover a part of the back surface of the flap portion 8c. The first lower electrode 91 also covers a part of the back surface of the flap portion 8c of the p-type layer 8.

A first upper electrode 92 is formed on the first lower electrode 91. The first lower electrode 91 and the first upper electrode 92 constitute a first electrode 9. A third insulating layer 11 is disposed between the first lower electrode 91 and the second electrode 10 and between the first upper electrode 92 and the second electrode 10.

An end portion 6a which is an outer end face of the flap portion 6c of the n-type layer 6 and an end portion 8a which is an outer end face of the flap portion 8c of the p-type layer 8 are each located above (on the back surface side of) a region R2 where the intrinsic layer 4 contacts the first insulating layer 5. A width W2 of the region R2 where the intrinsic layer 4 contacts the first insulating layer 5 can be, for example, 10 μm or more and 300 μm or less.

The end portion 6a of the n-type layer 6 is located on the back surface of the first insulating layer 5. The end portion 8a of the p-type layer 8 is located on the back surface of the second insulating layer 7. Accordingly, the end portion 8a of the p-type layer 8 is located above the end portion 6a of the n-type layer 6 with the second insulating layer 7 therebetween.

An end portion 91a of the first lower electrode 91 and an end portion 10a of the second electrode 10 each have a part located above the second insulating layer 7. In other words, the end portion 91a of the first lower electrode 91 above the flap portion 8c of the p-type layer 8 is located above the second insulating layer 7. The end portion 91a of the first lower electrode 91 and the end portion 10a of the second electrode 10 are located on the p-type layer 8 on the second insulating layer 7.

The first lower electrode 91, the first upper electrode 92, the second electrode 10, and the third insulating layer 11 also each have a shape that extends in a straight line in a direction normal to the plane of the paper of FIG. 1 as with the first insulating layer 5, the n-type layer 6, the second insulating layer 7, and the p-type layer 8. The end portion 9a which is an end face in a direction perpendicular to the direction in which the first lower electrode 91 extends and the end portion 10a which is an end face in a direction perpendicular to the direction in which the second electrode 10 extends each have a part located above the n-type layer 6 on the first insulating layer 5.

The thickness of the intrinsic layer 4 in a region R1 where the intrinsic layer 4 contacts the n-type layer 6 is t1. A width W1 of the region R1 where the intrinsic layer 4 contacts the n-type layer 6 can be, for example, 50 μm or more and 500 μm or less.

The thickness of the intrinsic layer 4 in a region R3 where the intrinsic layer 4 contacts the p-type layer 8 is t2. A width W3 of the region R3 where the intrinsic layer 4 contacts the p-type layer 8 can be, for example, 0.6 mm or more and 2 mm or less.

The back-surface-side structure of the semiconductor 1 has the structure described above. A texture structure 2 is formed on the front surface of the semiconductor 1 opposite the back surface. An antireflection film 3 that also serves as a passivation film is formed on the texture structure 2. The antireflection film 3 may be a laminated film in which an antireflection layer is formed on a passivation layer.

An example of a method for manufacturing a heterojunction-type back-contact cell of Embodiment 1 will now be described with reference to FIGS. 2 to 16. First, as illustrated in FIG. 2, an intrinsic layer 4 composed of i-type hydrogenated amorphous silicon is formed by, for example, a plasma CVD method on the entire back surface of the semiconductor 1 subjected to an RCA washing, and then a first insulating layer 5 is formed by, for example, a plasma CVD method on the entire back surface of the intrinsic layer 4. As described above, a texture structure (not shown) and an antireflection film (not shown) that also serves as a passivation film are formed on the front surface of the semiconductor 1. For the purposes of this specification, “i-type” means an intrinsic semiconductor.

The semiconductor 1 is not limited to n-type single-crystal silicon. For example, a known semiconductor may be used. The thickness of the semiconductor 1 is not particularly limited and can be, for example, 50 μm or more and 300 μm or less and is preferably 70 μm or more and 150 μm or less. The resistivity of the semiconductor 1 is also not particularly limited and can be, for example, 0.5 Ω·cm or more and 10 Ω·cm or less.

The texture structure on the front surface of the semiconductor 1 can be formed by, for example, texture-etching the entire front surface of the semiconductor 1.

The antireflection film that also serves as a passivation film of the front surface of the semiconductor 1 may be, for example, a silicon nitride film, a silicon oxide film, a laminate of a silicon nitride film and a silicon oxide film, or the like. The thickness of the antireflection film can be, for example, about 100 nm. The antireflection film can be formed by, for example, a sputtering method or a plasma CVD method.

The thickness of the intrinsic layer 4 formed on the entire back surface of the semiconductor 1 is not particularly limited and may be, for example, 1 nm or more and 10 nm or less. Specifically, the thickness may be about 4 nm.

The first insulating layer 5 formed on the entire back surface of the intrinsic layer 4 may be any layer composed of an insulating material. Preferably, the material can be etched substantially without affecting the intrinsic layer 4. The first insulating layer 5 may be, for example, a silicon nitride layer, a silicon oxide layer, or a laminate of a silicon nitride layer and a silicon oxide layer formed by a plasma CVD method or the like. In such a case, for example, hydrofluoric acid can be used so as to etch the first insulating layer 5 without substantially damaging the intrinsic layer 4. The thickness of the first insulating layer 5 is not particularly limited and can be, for example, about 100 nm.

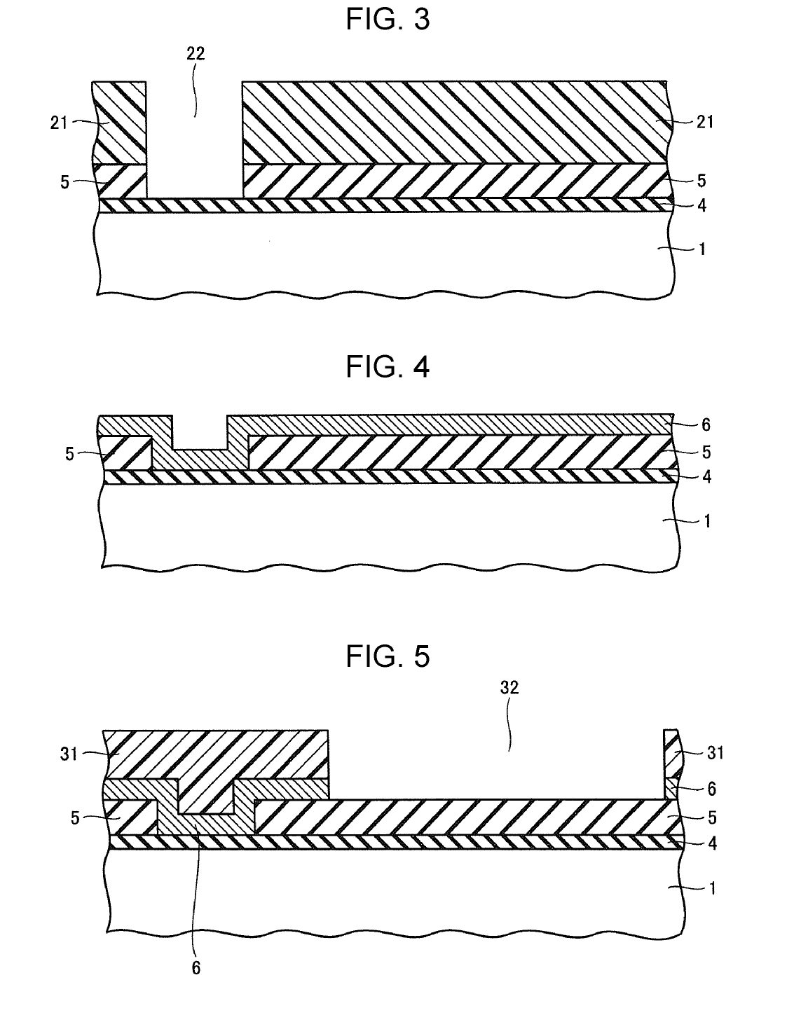

Next, as illustrated in FIG. 3, a resist 21 having an opening 22 is formed on the back surface of the first insulating layer 5. Then a portion of the first insulating layer 5 exposed in the opening 22 of the resist 21 is removed to expose the back surface of the intrinsic layer 4 in the opening 22 of the resist 21.

The resist 21 having the opening 22 can be formed by, for example, a photolithographic method, a printing method, or the like. The first insulating layer 5 may be removed by wet etching using hydrofluoric acid or the like, etching using an etching paste that contains hydrofluoric acid, or the like. For example, in the case where the first insulating layer 5 composed of silicon nitride and/or silicon oxide is removed by wet etching using hydrofluoric acid or the like or by etching using an etching paste containing hydrofluoric acid, hydrogenated amorphous silicon is less susceptible to hydrofluoric acid than silicon nitride and silicon oxide and thus the first insulating layer 5 can be selectively removed without substantially affecting the intrinsic layer 4 composed of i-type hydrogenated amorphous silicon. For example, in the case where the first insulating layer 5 is wet-etched using hydrofluoric acid (for example, a concentration of about 0.1 to 5%), the wet etching can be stopped at the back surface of the intrinsic layer 4.

Subsequently, the resist 21 is completely removed from the back surface of the first insulating layer 5. As illustrated in FIG. 4, an n-type layer 6 composed of n-type hydrogenated amorphous silicon is formed by, for example, a plasma CVD method so that the exposed back surface of the intrinsic layer 4 and the first insulating layer 5 are covered.

The thickness of the n-type layer 6 that covers the exposed back surface of the intrinsic layer 4 and the first insulating layer 5 is not particularly limited and can be, for example, about 10 nm.

The n-type impurity contained in the n-type layer 6 may be, for example, phosphorus, and the n-type impurity concentration in the n-type layer 6 can be, for example, about 5×10²⁰ atoms/cm³.

Next, as illustrated in FIG. 5, a resist 31 having an opening 32 is formed on the back surface of the n-type layer 6. Then a portion of the n-type layer 6 exposed in the opening 32 of the resist 31 is removed so as to expose the back surface of the first insulating layer 5 in the opening 32 of the resist 31.

The resist 31 having the opening 32 can be formed by, for example, a photolithographic method, a printing method, or the like. The n-type layer 6 can be selectively removed by, for example, wet etching using an aqueous alkaline solution, such as an aqueous tetramethylammonium hydroxide solution, an aqueous potassium hydroxide solution, or an aqueous sodium hydroxide solution, without substantially affecting the first insulating layer 5.

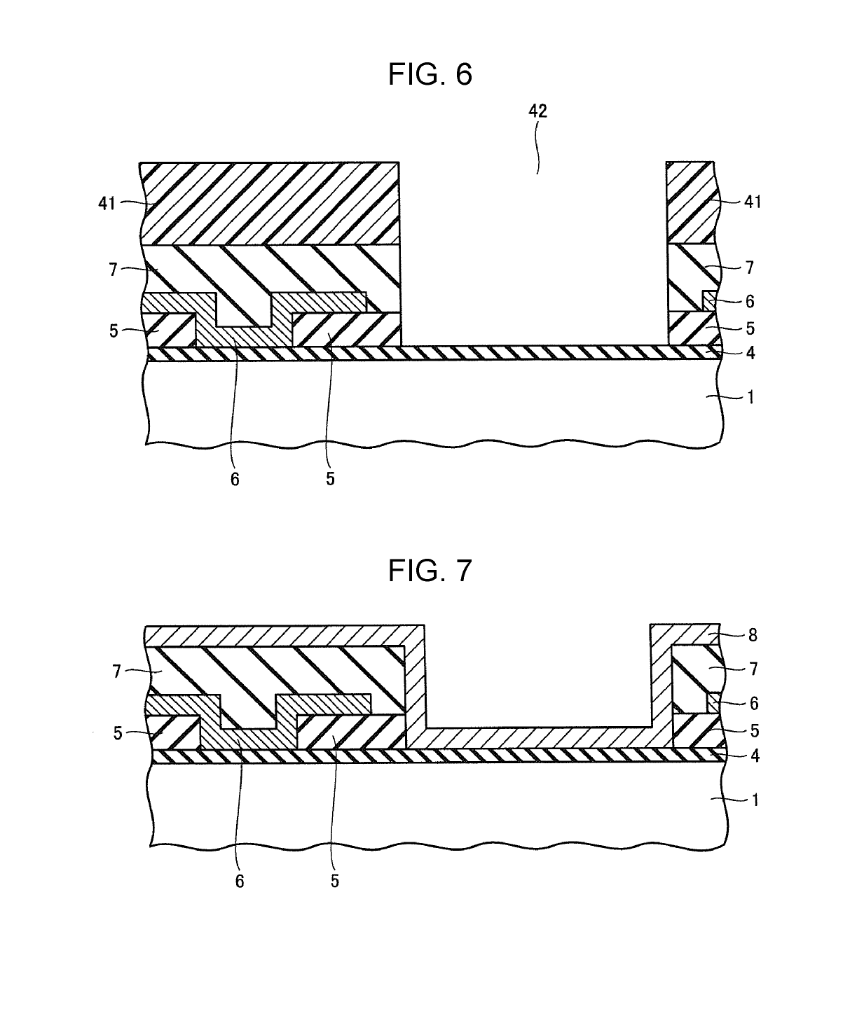

After the resist 31 is completely removed from the back surface of the n-type layer 6, an second insulating layer 7 is formed by, for example, a plasma CVD method, so as to cover the exposed back surface of the first insulating layer 5 and the n-type layer 6 as illustrated in FIG. 6. Then a resist 41 having an opening 42 is formed on the back surface of the second insulating layer 7. A portion of the second insulating layer 7 exposed in the opening 42 of the resist 41 and a portion of the first insulating layer 5 directly below are removed to expose the back surface of the intrinsic layer 4 in the opening 42 of the resist 41.

The second insulating layer 7 may be any layer composed of an insulating material but is preferably composed of a material that can be etched without substantially affecting hydrogenated amorphous silicon. For example, the second insulating layer 7 may be a silicon nitride film, a silicon oxide film, a laminate of a silicon nitride film and a silicon oxide film, or the like formed by a plasma CVD method or the like. In such a case, the first insulating layer 5 can be etched by using, for example, hydrofluoric acid without substantially damaging hydrogenated amorphous silicon. The thickness of the second insulating layer 7 is not particularly limited and may be, for example, 100 nm or more and 1000 nm or less.

The resist 41 having the opening 42 can be formed by, for example, a photolithographic method, a printing method, or the like. The second insulating layer 7 and the first insulating layer 5 can be removed by, for example, wet etching using hydrofluoric acid or by etching using an etching paste containing hydrofluoric acid. In the case where the first insulating layer 5 and the second insulating layer 7 each composed of silicon nitride and/or silicon oxide are removed by wet etching using hydrofluoric acid or the like or by etching using an etching paste containing hydrofluoric acid, hydrogenated amorphous silicon is less susceptible to hydrofluoric acid than silicon nitride and silicon oxide and thus the first insulating layer 5 and the second insulating layer 7 can be selectively removed without substantially affecting the intrinsic layer 4 composed of i-type hydrogenated amorphous silicon.

After the resist 41 is completely removed from the back surface of the second insulating layer 7, a p-type layer 8 composed of p-type hydrogenated amorphous silicon is formed by, for example, a plasma CVD method so as to cover the exposed back surface of the intrinsic layer 4 and the laminate that includes the first insulating layer 5, the n-type layer 6, and the second insulating layer 7, as illustrated in FIG. 7.

The thickness of the p-type layer 8 is not particularly limited and can be, for example, about 10 nm.

The p-type impurity contained in the p-type layer 8 can be, for example, boron. The p-type impurity concentration in the p-type layer 8 can be, for example, about 5×10²⁰ atoms/cm³.

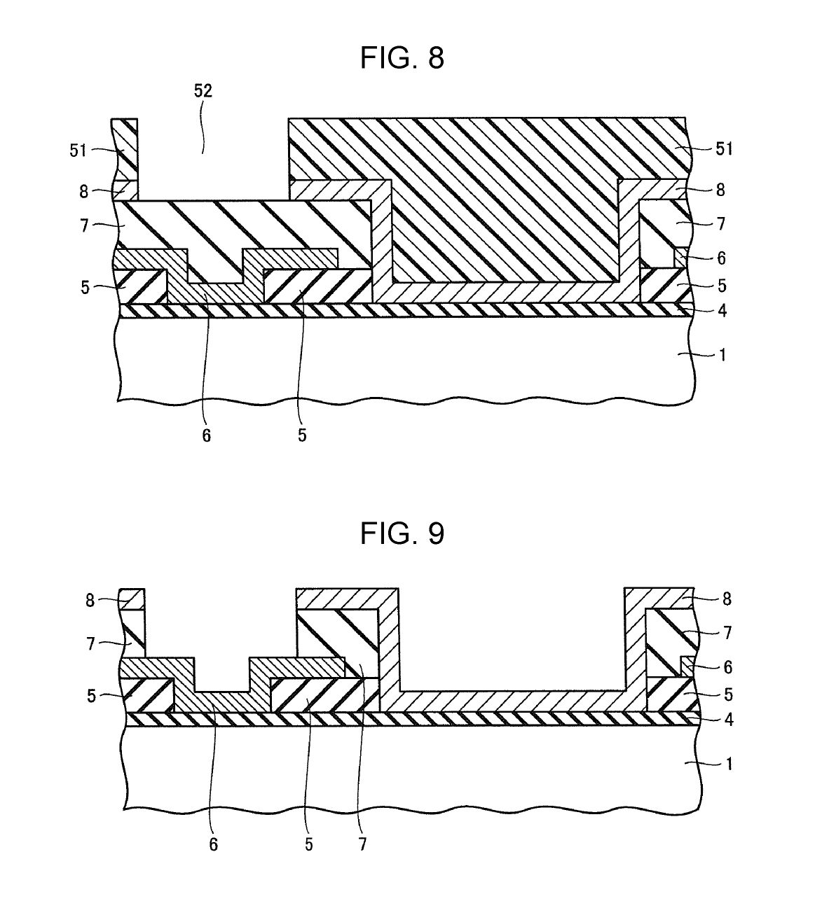

Next, as illustrated in FIG. 8, a resist 51 having an opening 52 is formed on the back surface of the p-type layer 8. Then a portion of the p-type layer 8 exposed in the opening 52 of the resist 51 is removed.

The resist 51 having the opening 52 can be formed by, for example, a photolithographic method, a printing method, or the like. The p-type layer 8 can be removed by, for example, wet etching using a mixture of hydrofluoric acid and nitric acid. A reactive ion etching method may be employed instead of wet etching.

In the case where the p-type layer 8 is wet-etched by using a mixture of hydrofluoric acid and nitric acid, the hydrofluoric acid/nitric acid mixing ratio (volume ratio) can be, for example, hydrofluoric acid:nitric acid=1:100. Wet-etching of the p-type layer 8 is preferably conducted slowly or by using a sufficiently thick second insulating layer 7 so as not to completely remove the second insulating layer 7 directly below the p-type layer 8 and expose the back surface of the n-type layer 6.

Next, as illustrated in FIG. 9, a portion of the second insulating layer 7 exposed in the opening 52 of the resist 51 is removed to expose the back surface of the n-type layer 6, and then the resist 51 is completely removed. The second insulating layer 7 can be removed by, for example, wet etching using hydrofluoric acid or the like or by etching using an etching paste containing hydrofluoric acid. For example, when the second insulating layer 7 composed of silicon nitride and/or silicon oxide is removed by wet etching using hydrofluoric acid or the like or by etching using an etching paste containing hydrofluoric acid, hydrogenated amorphous silicon is less susceptible to hydrofluoric acid than silicon nitride and silicon oxide and thus the second insulating layer 7 can be selectively removed without substantially affecting the n-type layer 6 composed of n-type hydrogenated amorphous silicon.

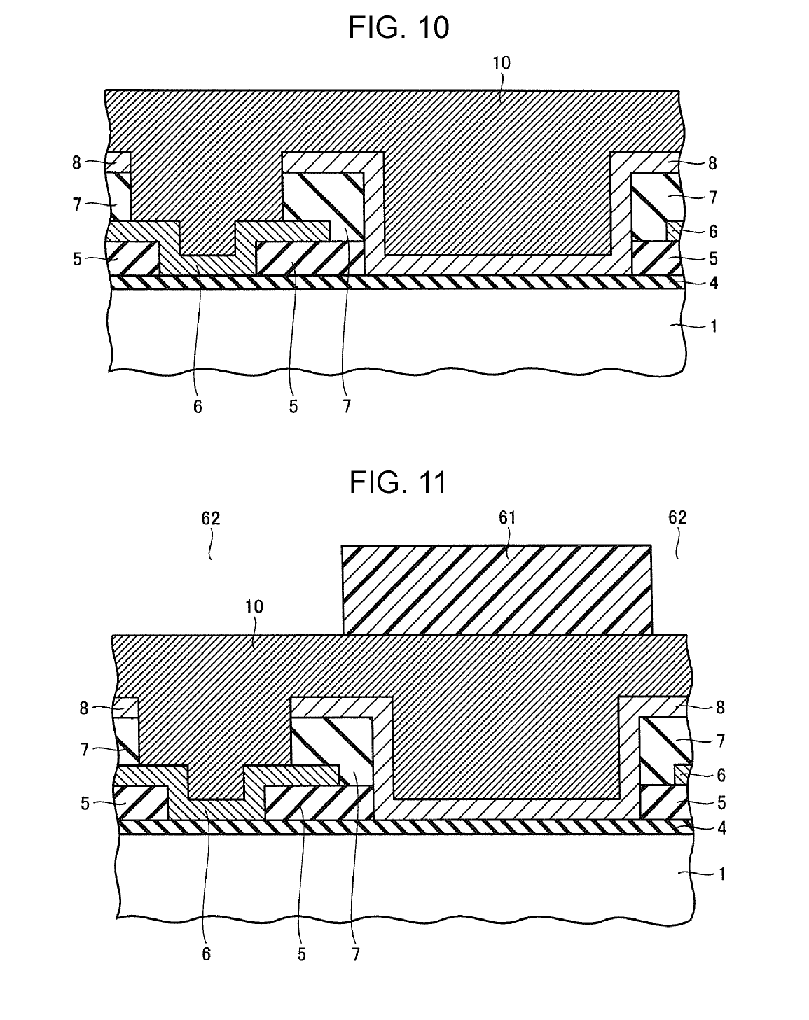

Then, as illustrated in FIG. 10, a second electrode 10 is formed on the back surface of the n-type layer 6 and the back surface of the p-type layer 8.

Any conductive material can be used as the second electrode 10 without any limitation but a material having a work function of 4.7 eV or more is preferably used. In particular, a material that contains at least one of platinum and ITO (indium tin oxide) is more preferably used. When a material having a work function of 4.7 eV or more is used as the second electrode 10 and in particular when a material that contains at least one of platinum and ITO is used, the resistance between the second electrode 10 and the p-type layer 8 can be decreased and the conversion efficiency of the photoelectric conversion element tends to increase.

The method for forming the second electrode 10 is not particularly limited. For example, a sputtering method, a vapor deposition method, or the like can be employed.

The second electrode 10 may be prepared by forming a metal layer such as silver or aluminum on an ITO layer, for example. When the second electrode 10 has a structure in which a metal layer is disposed on an ITO layer, the thickness of the ITO layer can be, for example, 5 nm or more and 100 nm or less and the thickness of the metal layer can be, for example, 1 μm or more and 5 μm or less.

Next, as illustrated in FIG. 11, a resist 61 having an opening 62 is formed on the back surface of the second electrode 10. The resist 61 having the opening 62 can be formed by, for example, a photolithographic method, a printing method, or the like.

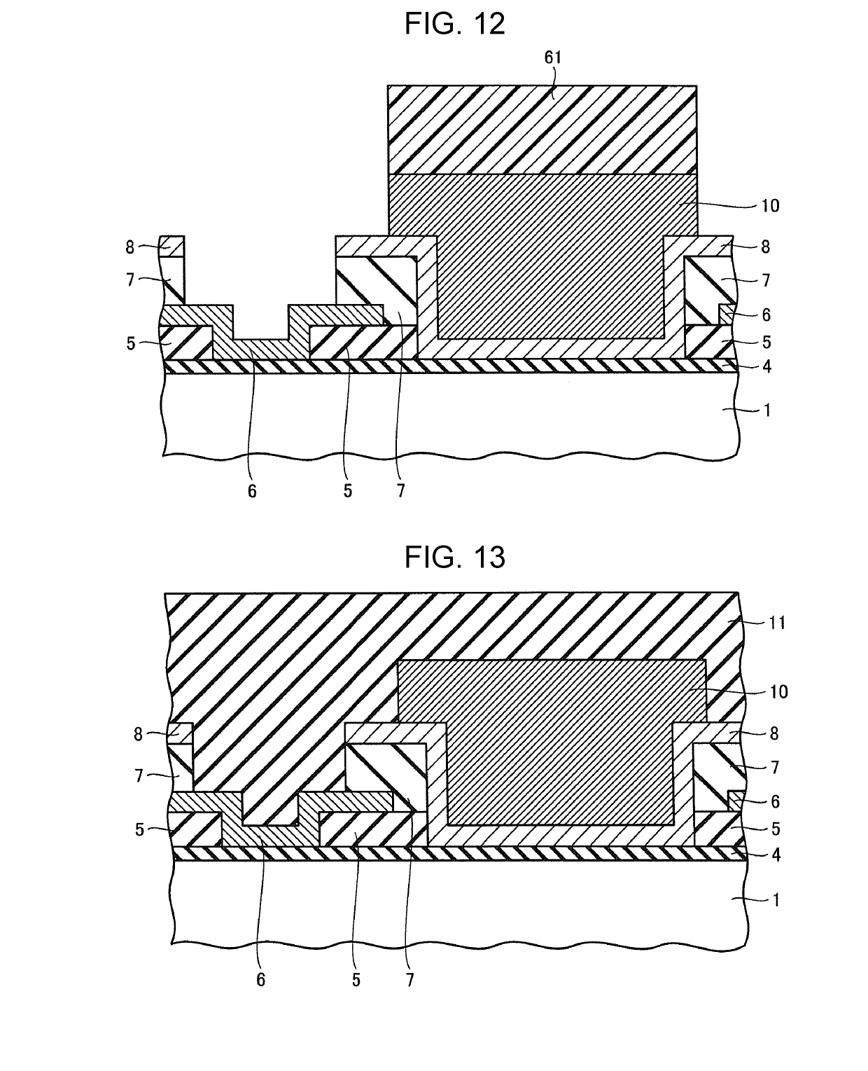

Next, as illustrated in FIG. 12, a portion of the second electrode 10 exposed in the opening 62 of the resist 61 is removed. In the case where the second electrode 10 is formed of a laminate constituted by an ITO layer and a silver layer on the ITO layer, a method that includes removing the silver layer by a commercially available silver etchant and then removing the ITO layer by hydrochloric acid or the like is possibly employed.

After completely removing the resist 61 from the back surface of the second electrode 10, as illustrated in FIG. 13, a third insulating layer 11 is formed by, for example, a plasma CVD method so as to cover the exposed back surface of the second electrode 10 and the n-type layer 6. Here, a part of the second electrode 10 is masked so as not to form the third insulating layer 11 thereon so that the second electrode 10 can be extracted outside.

The third insulating layer 11 is not particularly limited as long as it is a layer composed of an insulating material but is preferably composed of a material that can be etched without substantially affecting the n-type layer 6. The third insulating layer 11 may be a silicon nitride layer, a silicon oxide layer, or a laminate of a silicon nitride layer and a silicon oxide layer formed by a plasma CVD method or the like. In such a case, for example, hydrofluoric acid may be used to etch the first insulating layer 5 without substantially damaging the n-type layer 6. The thickness of the third insulating layer 11 is not particularly limited but may be, for example, 100 nm or more and 1000 nm or less.

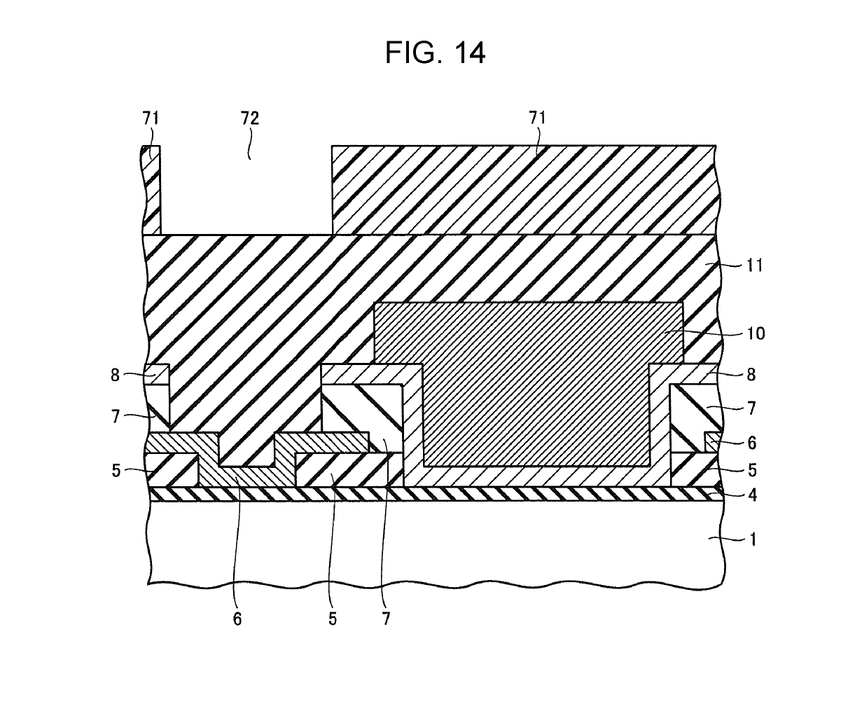

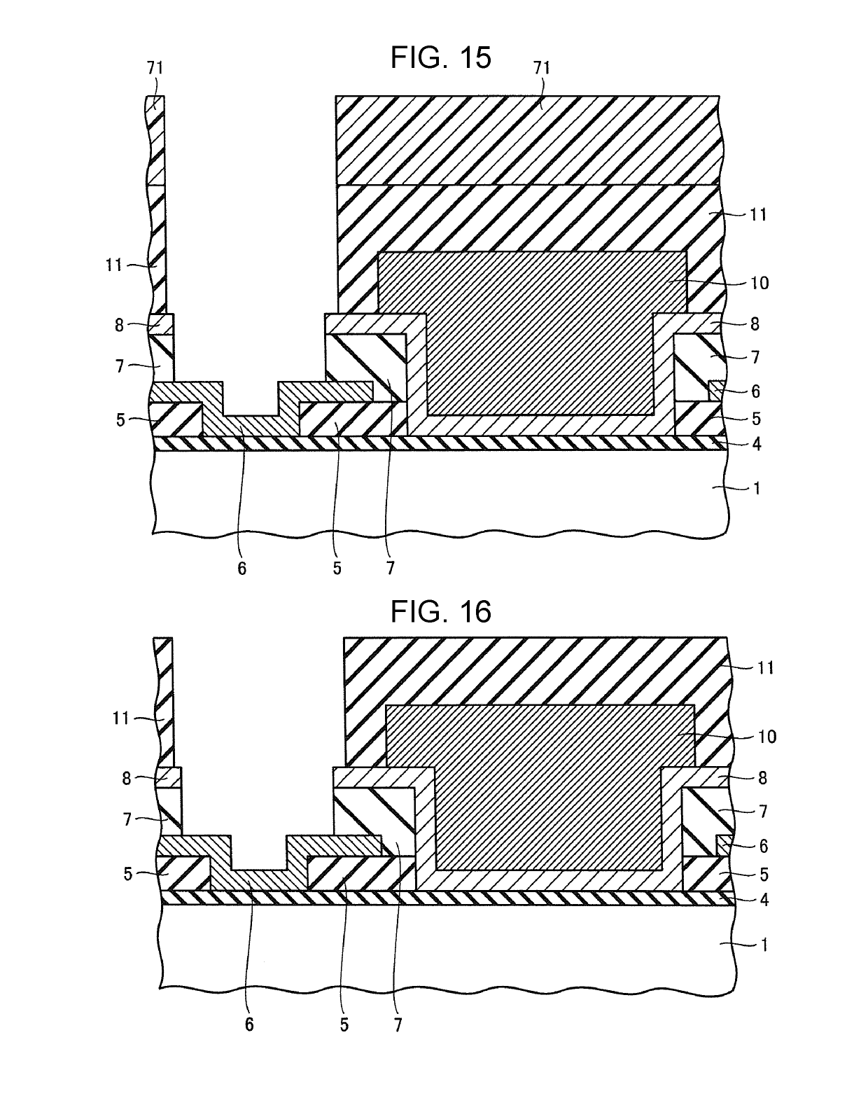

Next, as illustrated in FIG. 14, a resist 71 having an opening 72 is formed on the back surface of the second electrode 10. The resist 71 having the opening 72 can be formed by, for example, a photolithographic method or a printing method.

Next, as illustrated in FIG. 15, the third insulating layer 11 exposed in the opening 72 of the resist 71 is removed to expose the back surface of the n-type layer 6 in the opening 72 of the resist 71. The third insulating layer 11 can be removed by, for example, wet etching using hydrofluoric acid or the like. Since the n-type layer 6 is rarely susceptible to hydrofluoric acid, etching of the third insulating layer 11 by using hydrofluoric acid stops at the back surface of the n-type layer 6.

Next, as illustrated in FIG. 16, the resist 71 is completely removed from the back surface of the third insulating layer 11.

Next, as illustrated in FIG. 1, a first lower electrode 91 is formed on the back surface of the n-type layer 6 and then a first upper electrode 92 is formed so as to cover the back surfaces of the first lower electrode 91 and the third insulating layer 11 and form a first electrode 9. Here, a part of the second electrode 10 is masked so as not to form the first electrode 9 thereon so that the second electrode 10 can be extracted outside.

Any conductive material can be used as the first lower electrode 91 and the first upper electrode 92 without any limitation but a material having a work function less than 4.7 eV is preferably used. In particular, a material containing at least one of aluminum and zinc oxide is more preferably used. A material for the first lower electrode 91 and the first upper electrode 92 can be selected independently from the second electrode 10 or may be the same as the material of the second electrode 10. In the case where a material having a work function less than 4.7 eV is used as the first lower electrode 91 and the first upper electrode 92, in particular, in the case where a material containing at least one of aluminum and zinc oxide is used, the resistance between the first lower electrode 91 and the n-type layer 6 can be decreased and thus the conversion efficiency of the photoelectric conversion element tends to increase.

The method for forming the first electrode 9 is not particularly limited and, for example, a sputtering method, a vapor deposition method, or the like, can be used.

The first electrode 9 may be prepared by forming a metal layer of silver, aluminum, or the like on a zinc oxide layer, for example. In the case where the first electrode 9 has a structure in which a silver layer is disposed on a zinc oxide layer, the thickness of the zinc oxide layer can be, for example, 5 nm or more and 100 nm or less and the thickness of the silver layer can be, for example, 1 μm or more and 5 μm or less.

As described above, a heterojunction-type back-contact cell of Embodiment 1 can be manufactured.

As described above, in Embodiment 1, patterning of the n-type layer 6 and the p-type layer 8 can be conducted over the first insulating layer 5 and the second insulating layer 7. As a result, damage on the semiconductor 1 and the intrinsic layer 4 inflicted during patterning of the n-type layer 6 and the p-type layer 8 can be decreased, the heterojunction-type back-contact cell can be manufactured in high yield, and properties thereof can be enhanced.

In Embodiment 1, the first lower electrode 91 and the second electrode 10 can be formed in such a manner that the interelectrode distance L between the end portion 91a of the first lower electrode 91 and the end portion 10a of the second electrode 10 that are adjacent to and opposing each other is small. Thus, the amount of light that has entered the front surface of the semiconductor 1, has passed through the semiconductor 1, and is passing through the gap between the first lower electrode 91 and the second electrode 10 can be decreased and the amount of light reflected toward the semiconductor 1 side can be increased. Moreover, even if light passes through the gap between the first lower electrode 91 and the second electrode 10, the amount of light reflected toward the semiconductor 1 side can be increased due to the first upper electrode 92. Accordingly, the properties of the heterojunction-type back-contact cell can be enhanced.

In Embodiment 1, there is no need to use a shadow masking process to form the n-type layer 6 and the p-type layer 8. Thus, the n-type layer 6 and the p-type layer 8 can be highly accurately formed, the heterojunction-type back-contact cell can be manufactured in high yield, and the properties thereof can be enhanced.

In Embodiment 1, parasitic resistance can be decreased since the first electrode 9 has a two-layer electrode structure constituted by the first lower electrode 91 and the first upper electrode 92.

Moreover, in Embodiment 1, the material for the first electrode 9 on the n-type layer 6 and the material for the second electrode 10 on the p-type layer 8 can be independently selected. Thus, a material having an optimum work function for each of the first electrode 9 and the second electrode 10 can be selected, and parasitic resistance can thus be decreased.

In particular, in Embodiment 1, the end portion 6a of the n-type layer 6 and the end portion 8a of the p-type layer 8 are located above the first insulating layer 5 in the region R2 where the intrinsic layer 4 contacts the first insulating layer 5. Accordingly, patterning of the n-type layer 6 and the p-type layer 8 can be conducted over the first insulating layer 5 and thus the damage on the semiconductor 1 and the intrinsic layer 4 inflicted during patterning of the n-type layer 6 and the p-type layer 8 can be decreased.

In Embodiment 1, the end portion 8a of the p-type layer 8 is located above the end portion 6a of the n-type layer 6 with the second insulating layer 7 therebetween. Accordingly, the n-type layer 6 and the p-type layer 8 can be insulated from each other in the thickness direction by the second insulating layer 7. Moreover, since the second insulating layer 7 is disposed between the n-type layer 6 and the p-type layer 8, patterning of the p-type layer 8 can be conducted without substantially damaging the n-type layer 6.

In Embodiment 1, the end portion 91a of the first lower electrode 91 and the end portion 10a of the second electrode 10 are located on the second insulating layer 7. Accordingly, patterning of the first lower electrode 91 and the second electrode 10 can be conducted over the second insulating layer 7 and thus damage on the semiconductor 1, the intrinsic layer 4, the n-type layer 6, and the p-type layer 8 inflicted during patterning of the first lower electrode 91 and the second electrode 10 can be decreased. In this case, the interelectrode distance L between the end portion 91a of the first lower electrode 91 and the end portion 10a of the second electrode 10 that are adjacent to and opposing each other can be decreased, the amount of light passing through the gap between the first lower electrode 91 and the second electrode 10 can be decreased, and the amount of light reflected toward the semiconductor 1 side can be increased. Thus, properties of the heterojunction-type back-contact cell can be improved.

In Embodiment 1, the end portion 9a of the first lower electrode 91 and the end portion 10a of the second electrode 10 are located on the p-type layer 8 on the second insulating layer 7. Accordingly, patterning of the first lower electrode 9 and the second electrode 10 can be conducted over the second insulating layer 7, and damage on the semiconductor 1, the intrinsic layer 4, the n-type layer 6, and the p-type layer 8 inflicted during patterning of the first lower electrode 91 and the second electrode 10 can be decreased. In such a case, the interelectrode distance L between the end portion 9a of the first lower electrode 91 and the end portion 10a of the second electrode 10 that are adjacent to and opposing each other can be decreased, the amount of light passing through the gap between the first lower electrode 91 and the second electrode 10 can be decreased, and the amount of light reflected toward the semiconductor 1 side can be increased. Thus, properties of the heterojunction-type back-contact cell can be improved.

In Embodiment 1, the p-type layer 8 preferably has a conductivity of 0.28 S/cm or less. In such a case, the interelectrode distance L between the first lower electrode 91 and the second electrode 10 can be decreased to 10 μm or less. Thus, the amount of light passing through the gap between the first lower electrode 91 and the second electrode 10 can be decreased, and the amount of light reflected toward the semiconductor 1 side can be increased. Thus, properties of the heterojunction-type back-contact cell can be improved.

In Embodiment 1, the p-type layer 8 is formed after formation of the n-type layer 6. Accordingly, a satisfactory passivation effect can be obtained at the back surface of the semiconductor 1 by the intrinsic layer 4. In other words, if the p-type layer 8 is formed before the n-type layer 6, the effect of annealing during formation of the n-type layer 6 may decrease the minor carrier lifetime of the intrinsic layer 4 covered with the p-type layer 8. However, if the p-type layer 8 is formed after the n-type layer 6, such a decrease in minor carrier lifetime can be decreased.

In Embodiment 1, the thickness t2 of the intrinsic layer 4 in the region R3 that contacts the p-type layer 8 is preferably larger than the thickness t1 of the intrinsic layer 4 in the region R1 that contacts the n-type layer 6. When the thickness t2 of the intrinsic layer 4 directly below the p-type layer 8 is larger than the thickness t1 of the intrinsic layer 4 directly below the n-type layer 6, a satisfactory passivation effect can be obtained at the back surface of the semiconductor 1 by the intrinsic layer 4.

In the description above, the first conductivity type is assumed to be the n-type and the second conductivity type is assumed to be the p-type. Alternatively, the first conductivity type may be assumed to be the p-type and the second conductivity type may be assumed to be the n-type, naturally.

In the description above, the case of using n-type hydrogenated amorphous silicon in the n-type layer 6 has been described but the n-type layer 6 is not limited to this. Alternatively, n-type microcrystalline silicon or the like may be used.

In the description above, the case of using p-type hydrogenated amorphous silicon in the p-type layer 8 has been described but the p-type layer 8 is not limited to this. Alternatively, p-type microcrystalline silicon or the like may be used.

### Embodiment 2

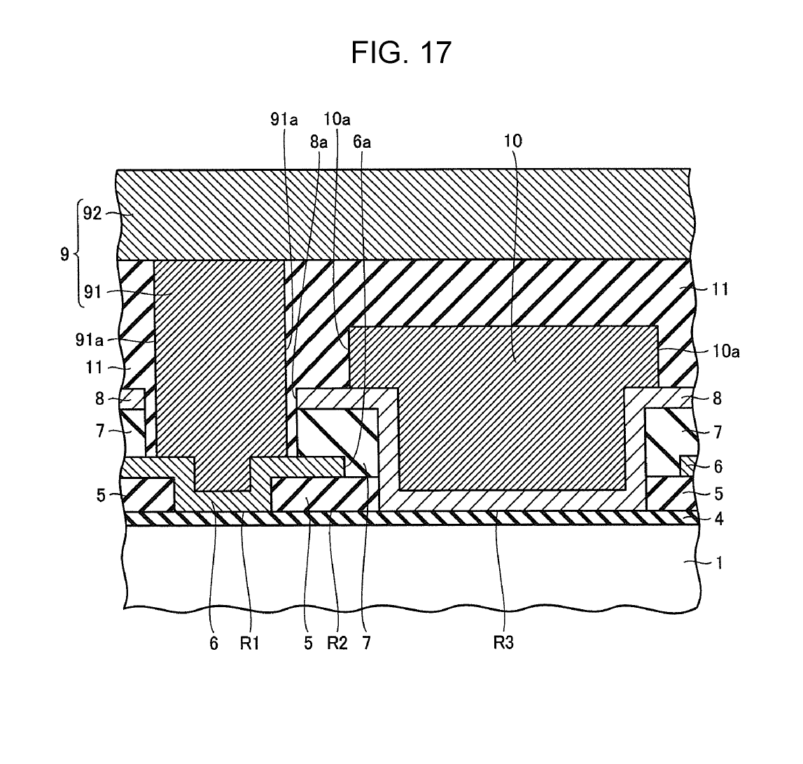

FIG. 17 is a schematic cross-sectional view of a heterojunction-type back-contact cell according to Embodiment 2 which is another example of a photoelectric conversion element of the present invention. The heterojunction-type back-contact cell of Embodiment 2 is characterized in that the end portion 9a of the first lower electrode 91 is located on the back surface of the n-type layer 6 and the end portion 10a of the second electrode 10 is located on the back surface of the p-type layer 8.

In Embodiment 2 also, the end portion 6a of the n-type layer 6 and the end portion 8a of the p-type layer 8 are located above the first insulating layer 5 in the region R2 where the intrinsic layer 4 contacts the first insulating layer 5, and thus patterning of the n-type layer 6 and the p-type layer 8 can be conducted over the first insulating layer 5. Accordingly, in Embodiment 2 also, damage on the semiconductor 1 and the intrinsic layer 4 can be decreased, the heterojunction-type back-contact cell can be manufactured in high yield, and properties thereof can be enhanced. Since the n-type layer 6 and the p-type layer 8 are insulated from each other in the thickness direction by the second insulating layer 7, shunt resistance between the first electrode 9 and the second electrode 10 can be significantly increased.

The heterojunction-type back-contact cell of Embodiment 2 differs from the heterojunction-type back-contact cell of Embodiment 1 in which the end portion 9a of the first lower electrode 91 is located on the back surface of the p-type layer 8, in that the end portion 9a of the first lower electrode 91 is located on the back surface of the p-type layer 8. However, in the case where the p-type layer 8 is composed of p-type hydrogenated amorphous silicon, any of the structures of Embodiment 1 and Embodiment 2 can be employed.

In the case where the p-type layer 8 is composed of p-type microcrystalline silicon which has higher conductivity than p-type hydrogenated amorphous silicon, the heterojunction-type back-contact cell structure of Embodiment 2 is preferable. In such a case, the heterojunction-type back-contact cell structure of Embodiment 1 may be employed if the interelectrode distance L between the end portion 9a of the first lower electrode 91 and the end portion 10a of the second electrode 10 is sufficiently large; however, it becomes increasingly difficult to increase the amount of light reflected toward the semiconductor 1 side as the interelectrode distance L increases.

In the case where the conductivity type is exchanged between the n-type and the p-type, the heterojunction-type back-contact cell structure of Embodiment 1 is preferable. In such a case also, the heterojunction-type back-contact cell structure of Embodiment 2 may be employed if the interelectrode distance L between the end portion 9a of the first lower electrode 91 and the end portion 10a of the second electrode 10 is sufficiently large; however, it becomes increasingly difficult to increase the amount of light reflected toward the semiconductor 1 side as the interelectrode distance L increases.

Since features of Embodiment 2 other than those described above are identical to those of Embodiment 1, the description therefor is omitted.

### Embodiment 3

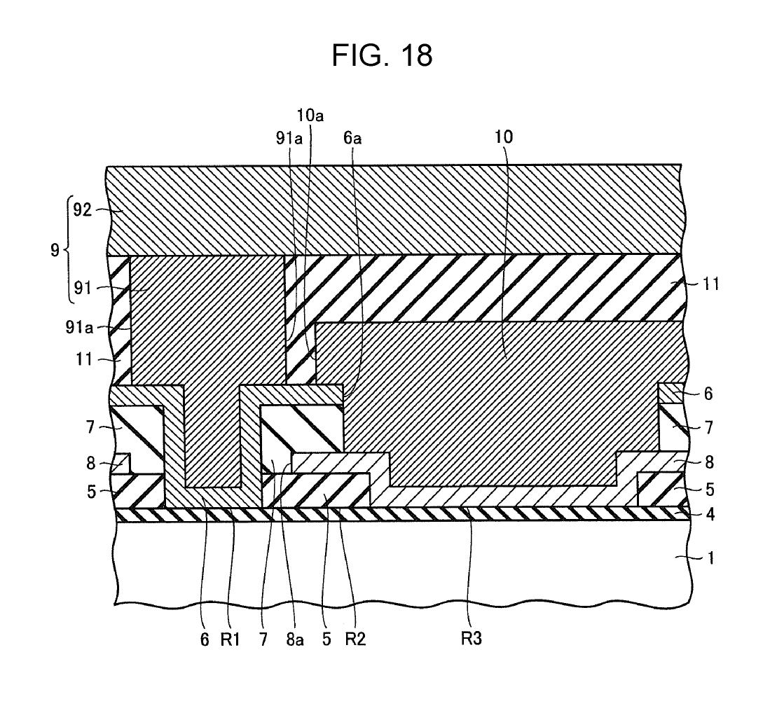

FIG. 18 is a schematic cross-sectional view of a heterojunction-type back-contact cell according to Embodiment 3 which is another example of a photoelectric conversion element of the present invention. The heterojunction-type back-contact cell of Embodiment 3 is characterized in that the n-type layer 6 is formed after the p-type layer 8 is formed.

In Embodiment 3 also, the end portion 6a of the n-type layer 6 and the end portion 8a of the p-type layer 8 are located above the first insulating layer 5 in the region R2 where the intrinsic layer 4 contacts the first insulating layer 5, and patterning of the n-type layer 6 and the p-type layer 8 can be conducted over the first insulating layer 5. Accordingly, in Embodiment 3 also, damage on the semiconductor 1 and the intrinsic layer 4 can be decreased, the heterojunction-type back-contact cell can be manufactured in high yield, and properties thereof can be enhanced. Since the n-type layer 6 and the p-type layer 8 are insulated from each other in the thickness direction by the second insulating layer 7, shunt resistance between the first electrode 9 and the second electrode 10 can be significantly increased.

Since features of Embodiment 3 other than those described above are identical to those of Embodiment 1 and Embodiment 2, the description therefor is omitted.

Described below are other aspects of the present invention, namely, a photoelectric conversion module (Embodiment 4) and solar power generation systems (Embodiments 5 and 6) equipped with the heterojunction-type back-contact cells of Embodiments 1 to 3.

Since the heterojunction-type back-contact cells of Embodiments 1 to 3 have enhanced properties, the photoelectric conversion module and the solar power generation systems equipped with the heterojunction-type back-contact cells also have enhanced properties.

### Embodiment 4

Embodiment 4 is a photoelectric conversion module that uses the heterojunction-type back-contact cells of Embodiments 1 to 3 as photoelectric conversion elements.

### <Photoelectric Conversion Module>

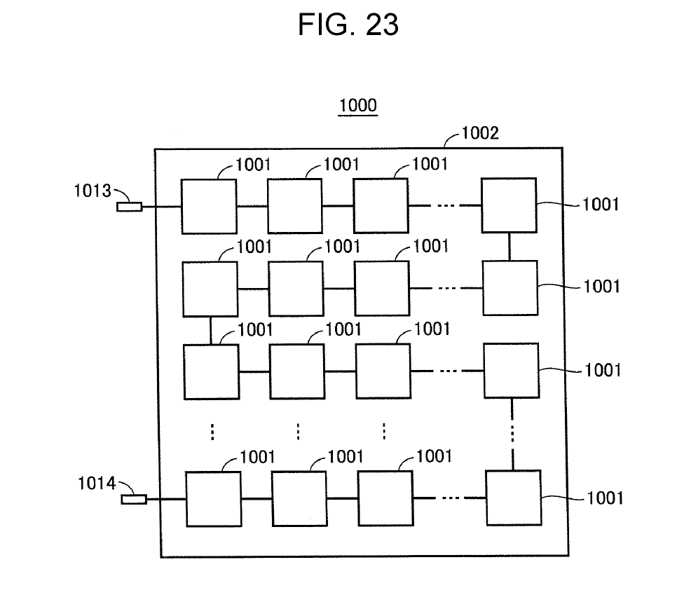

FIG. 23 is a schematic diagram illustrating a structure of a photoelectric conversion module according to Embodiment 4 which is an example of a photoelectric conversion module of the present invention that uses heterojunction-type back-contact cells of Embodiments 1 to 3 as photoelectric conversion elements. Referring to FIG. 23, a photoelectric conversion module 1000 of Embodiment 4 includes plural photoelectric conversion elements 1001, a cover 1002, and output terminals 1013 and 1014.

The photoelectric conversion elements 1001 are arranged into an array and connected in series. FIG. 23 illustrates an arrangement in which the photoelectric conversion elements 1001 are connected in series but the arrangement and the connection mode are not limited to these. The elements may be connected in parallel or both in series and in parallel. The photoelectric conversion elements 1001 are each one of the heterojunction-type back-contact cells of Embodiments 1 to 3. Note that the photoelectric conversion module 1000 is not limited by the description above and may take any structure as long as at least one of the photoelectric conversion elements 1001 is formed of any one of the photoelectric conversion elements of Embodiments 1 to 3. The number of photoelectric conversion elements 1001 included in the photoelectric conversion module 1000 can be any integer equal to or greater than 2.

The cover 1002 is formed of a weatherproof cover and covers the photoelectric conversion elements 1001.

The output terminal 1013 is connected to the photoelectric conversion element 1001 arranged at one end of the photoelectric conversion elements 1001 connected in series.

The output terminal 1014 is connected to the photoelectric conversion element 1001 arranged at the other end of the photoelectric conversion element 1001 connected in series.

### Embodiment 5

Embodiment 5 is a solar power generation system that uses heterojunction-type back-contact cells of Embodiments 1 to 3 as photoelectric conversion elements. Since the photoelectric conversion elements have enhanced properties (conversion efficiency, etc.), the solar power generation system of the present invention of the present invention equipped with such elements can also have enhanced properties. A solar power generation system is an apparatus that appropriately converts power output from the photoelectric conversion modules so that the power can be supplied to commercial power network or electrical appliances etc.

### <Solar Power Generation System>

A solar power generation system is an apparatus that appropriately converts power output from the photoelectric conversion modules so that the power can be supplied to commercial power network or electrical appliances etc.

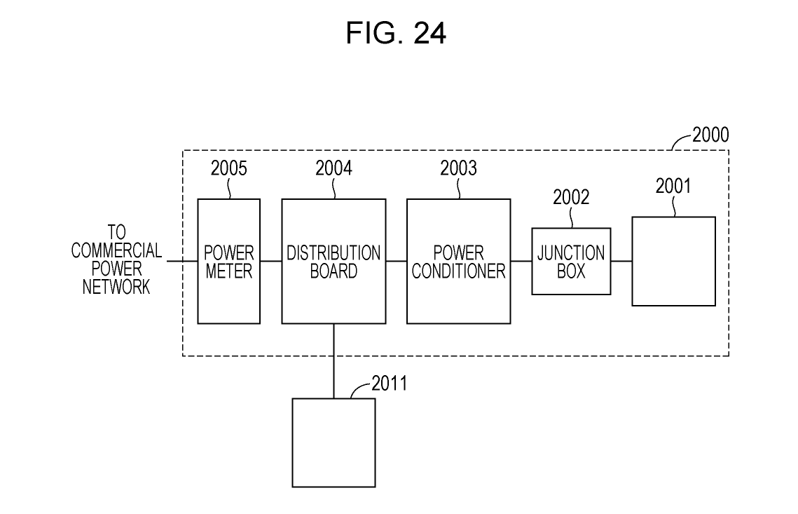

FIG. 24 is a schematic diagram illustrating a structure of a solar power generation system of Embodiment 5 which is an example of a solar power generation system of the present invention in which heterojunction-type back-contact cells of Embodiments 1 to 3 are used as photoelectric conversion elements. Referring to FIG. 24, a solar power generation system 2000 of Embodiment 5 includes a photoelectric conversion module array 2001, a junction box 2002, a power conditioner 2003, a distribution board 2004, and a power meter 2005. As described below, the photoelectric conversion module array 2001 is constituted by plural photoelectric conversion modules 1000 (Embodiment 4).

In general, the solar power generation system 2000 is used in combination with a “home energy management system (HEMS)”, a “building energy management system (BEMS)”, or the like that monitors the amount of power generated by the solar power generation system 2000, and monitors and controls the amount of power consumed by electric appliances connected to the solar power generation system 2000 so as to cut down the energy consumption.

The junction box 2002 is connected to the photoelectric conversion module array 2001. The power conditioner 2003 is connected to the junction box 2002. The distribution board 2004 is connected to the power conditioner 2003 and an electrical appliance 2011. The power meter 2005 is connected to the distribution board 2004 and to a commercial power network. Note that a storage battery may be connected to the power conditioner 2003. In such a case, output fluctuation caused by fluctuation in amount of sunlight can be decreased and the power stored in the storage battery can be supplied to the electrical appliance 2011 or the commercial power network even in the time zone where sunshine is not available. The storage battery may be built inside the power conditioner 2003.

### <Operation>

The operation of the solar power generation system 2000 of Embodiment 5 is, for example, as follows.

The photoelectric conversion module array 2001 converts sunlight into electricity to generate DC power and supplies DC power to the junction box 2002.

The junction box 2002 receiving the DC power generated by the photoelectric conversion module array 2001 supplies the DC power to the power conditioner 2003.

The power conditioner 2003 converts DC power supplied from the junction box 2002 into AC power and supplies AC power to the distribution board 2004. Here, part of the DC power supplied from the junction box 2002 may remain unconverted and be supplied to the distribution board 2004 as is. Note that in the case where a storage battery is connected to the power conditioner 2003 (or a storage battery is built inside the power conditioner 2003), the power conditioner 2003 converts all or part of the DC power supplied from the junction box 2002 into an appropriate form of power so that the power can be stored in the storage battery. The power stored in the storage battery is supplied to the power conditioner 2003 side as needed depending on the amount of power generated by the photoelectric conversion module or the status of power consumption of the electrical appliance 2011, converted into an appropriate form of power, and supplied to the distribution board 2004.

The distribution board 2004 supplies to the electrical appliance 2011 at least one of the AC power supplied from the power conditioner 2003 and the commercial power supplied through the power meter 2005. If the AC power supplied from the power conditioner 2003 is larger than the power consumed by the electrical appliance 2011, the distribution board 2004 supplies to the electrical appliance 2011 the AC power supplied from the power conditioner 2003. The excess AC power is supplied to the commercial power network through the power meter 2005.

When the AC power supplied to the distribution board 2004 from the power conditioner 2003 is smaller than the power consumed by the electrical appliance 2011, the distribution board 2004 supplies to the electrical appliance 2011 AC power supplied from the commercial power network and AC power supplied from the power conditioner 2003.

The power meter 2005 measures the power that flows from the commercial power network to the distribution board 2004 and the power that flows from the distribution board 2004 to the commercial power network.

### <Photoelectric Conversion Module Array>

The photoelectric conversion module array 2001 will now be described.

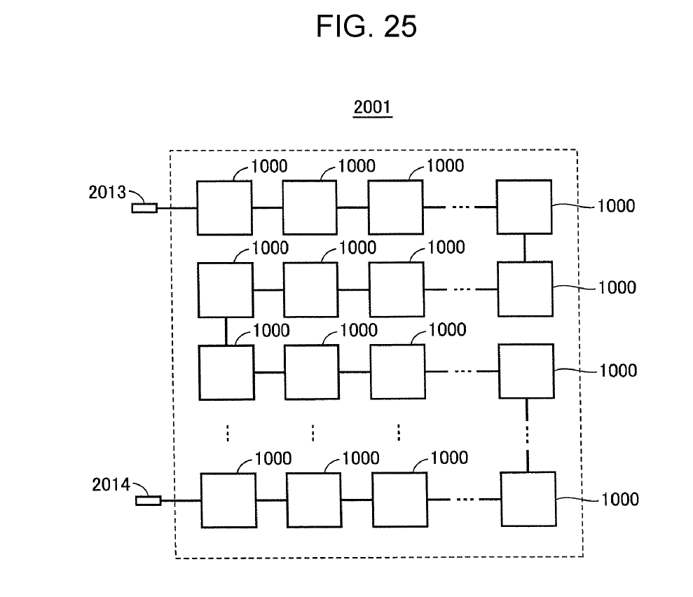

FIG. 25 is a schematic diagram illustrating an example of a structure of the photoelectric conversion module array 2001 illustrated in FIG. 24. Referring to FIG. 25, the photoelectric conversion module array 2001 includes plural photoelectric conversion modules 1000 and output terminals 2013 and 2014.

The photoelectric conversion modules 1000 are arranged into an array and connected in series. FIG. 25 illustrates an arrangement in which the photoelectric conversion modules 1000 are connected in series but the arrangement and the connection mode are not limited to these. The modules may be connected in parallel or both in series and in parallel. The number of the photoelectric conversion modules 1000 included in the photoelectric conversion module array 2001 can be any integer equal to or greater than 2.

The output terminal 2013 is connected to the photoelectric conversion module 1000 located at one end of the photoelectric conversion modules 1000 connected in series.

The output terminal 2014 is connected to the photoelectric conversion module 1000 located at the other end of the photoelectric conversion modules 1000 connected in series.

The description above is merely exemplary and the solar power generation system of Embodiment 5 may have any structure not limited by the description above as long as at least one of heterojunction-type back-contact cells of Embodiments 1 to 3 is included.

### Embodiment 6

Embodiment 6 is a solar power generation system whose scale is larger than that of the solar power generation system described in Embodiment 5. The solar power generation system of Embodiment 6 also includes at least one of heterojunction-type back-contact cells of Embodiments 1 to 3. Since the photoelectric conversion elements of the present invention have enhanced properties (conversion efficiency etc.), the solar power generation system of the present invention equipped with such elements can have enhanced properties.

<Large-Scale Solar Power Generation System>

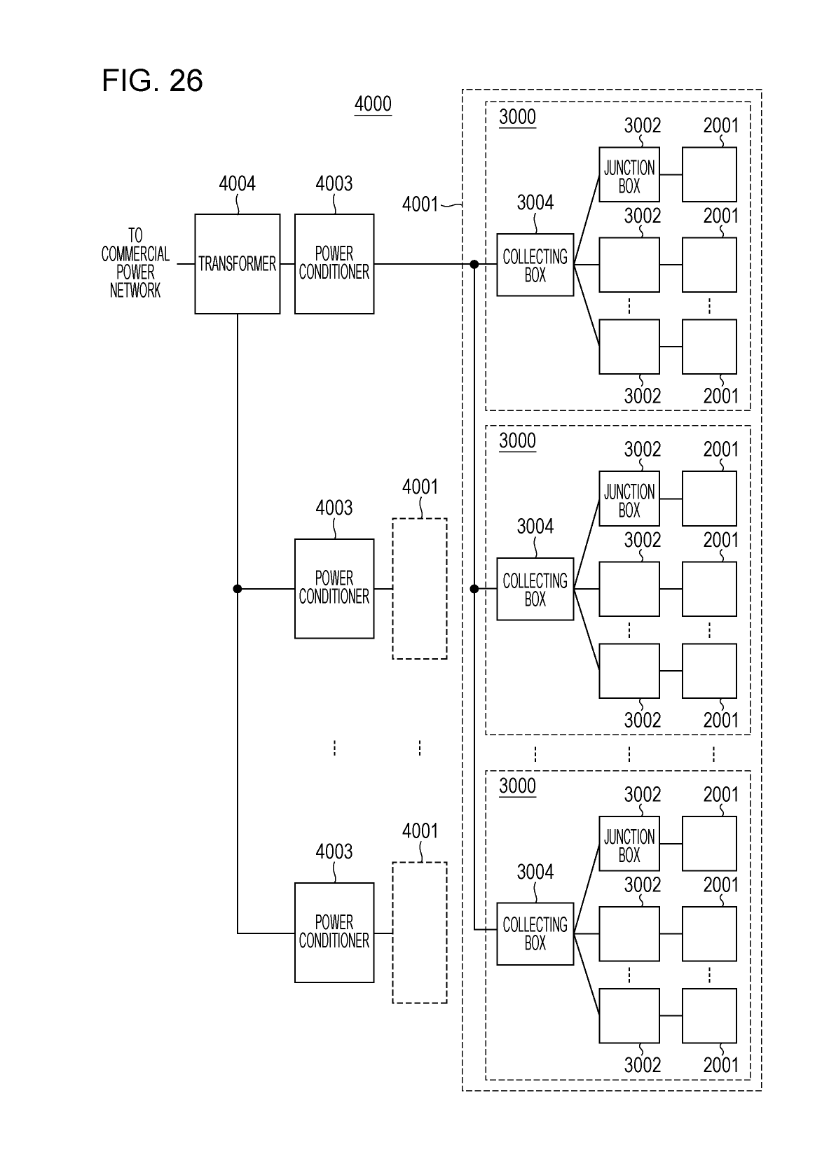

FIG. 26 is a schematic diagram illustrating a structure of a solar power generation system of Embodiment 6 which is an example of a large-scale solar power generation system of the present invention. Referring to FIG. 26, a solar power generation system 4000 of Embodiment 6 includes plural subsystems 4001, plural power conditioners 4003, and a transformer 4004. The scale of the solar power generation system 4000 is larger than the scale of the solar power generation system 2000 of Embodiment 5 illustrated in FIG. 25.

The power conditioners 4003 are respectively connected to the subsystems 4001. In the solar power generation system 4000, the number of power conditioners 4003 and the number of subsystems 4001 connected to the power conditioners 4003 may each be any integer equal to or greater than 2. Note that a storage battery may be connected to the power conditioner 4003. In such a case, output fluctuation caused by fluctuation in amount of sunlight can be decreased and the power stored in the storage battery can be supplied even in the time zone where sunshine is not available. The storage battery may be built inside the power conditioner 4003.

The transformer 4004 is connected to the power conditioners 4003 and the commercial power network.

Each of the subsystems 4001 is constituted by plural module systems 3000. The number of module systems 3000 in each subsystem 4001 may be any integer equal to or greater than 2.

Each of the module systems 3000 includes plural photoelectric conversion module arrays 2001, plural junction boxes 3002, and a collecting box 3004. The number of the junction boxes 3002 and the number of photoelectric conversion module arrays 2001 connected to the junction boxes 3002 in the module system 3000 may be any integer equal to or greater than 2.

The collecting box 3004 is connected to the junction boxes 3002. The power conditioner 4003 is connected to the collecting boxes 3004 in the subsystems 4001.

### <Operation>

The operation of the solar power generation system 4000 of Embodiment 6 is, for example, as follows.

The photoelectric conversion module arrays 2001 in the module system 3000 convert sunlight into electricity to generate DC power and supply the DC power to the collecting box 3004 via the junction boxes 3002. The collecting boxes 3004 in the subsystem 4001 supply DC power to the power conditioner 4003. The power conditioners 4003 convert the DC power into AC power and supply AC power to the transformer 4004. Note that in the case where a storage battery is connected to the power conditioner 4003 (or a storage battery is built inside the power conditioner 4003), the power conditioner 4003 converts all or part of the DC power supplied from the collecting box 3004 into an appropriate form of power so that the power can be stored in the storage battery. The power stored in the storage battery is supplied to the power conditioner 4003 side as needed depending on the amount of power generated by the subsystem 4001, converted into an appropriate form of power, and supplied to the transformer 4004.

The transformer 4004 converts the voltage level of the AC power supplied from the power conditioners 4003 and supplies power to the commercial power network.

The solar power generation system 4000 needs to include at least one of the heterojunction-type back-contact cells of Embodiments 1 to 3 and not all of the photoelectric conversion elements in the solar power generation system 4000 need to be the heterojunction-type back-contact cells of Embodiments 1 to 3. For example, it is possible that all of the photoelectric conversion elements in a particular subsystem 4001 are heterojunction-type back-contact cells of Embodiments 1 to 3 while some or all of the photoelectric conversion elements in another subsystem 4001 are not heterojunction-type back-contact cells of Embodiments 1 to 3.

### Example 1

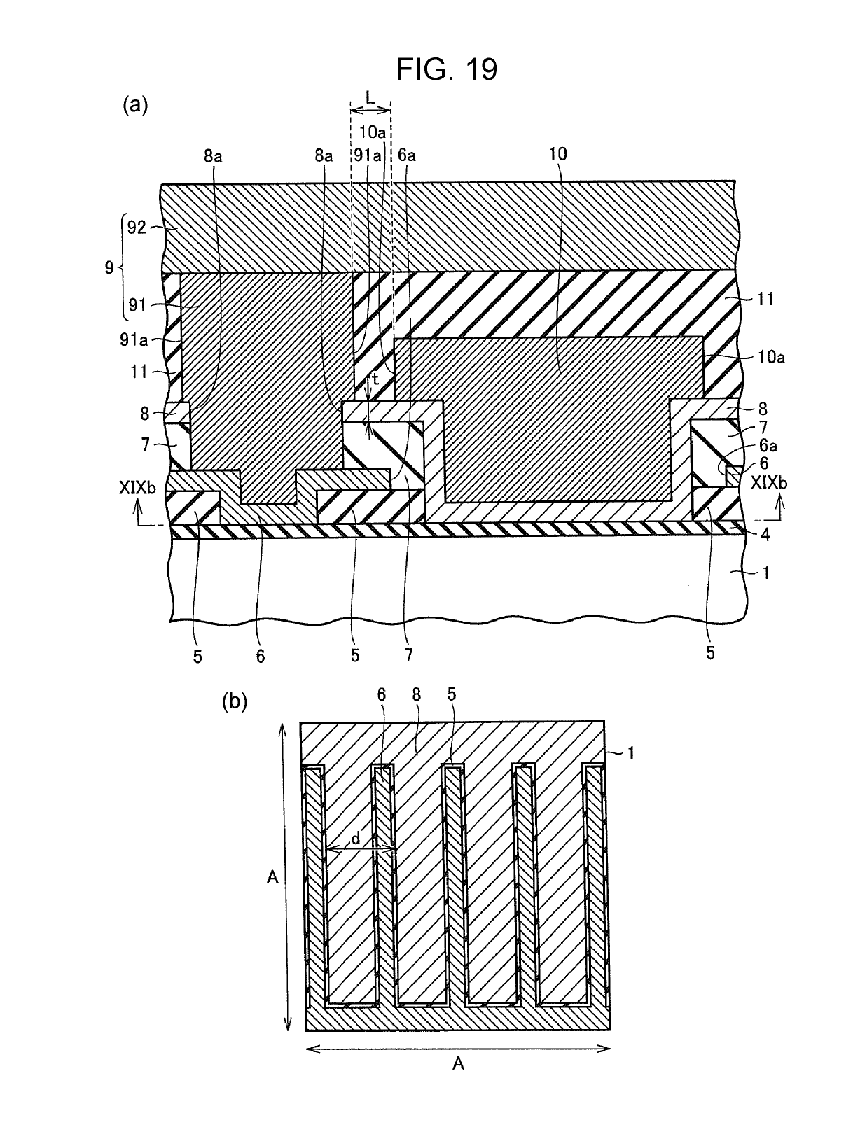

FIG. 19(a) illustrates a cross-sectional structure of a heterojunction-type back-contact cell of Example 1 and FIG. 19(b) is a schematic cross-sectional view taken along XIXb-XIXb of FIG. 19(a). In FIG. 19(a), L represents the interelectrode distance between the end portion 91a of the first lower electrode 91 and the end portion 10a of the second electrode 10 that are adjacent to each other, and t represents the thickness of the p-type layer 8. In FIG. 19(b), A represents the length of one side of the heterojunction-type back-contact cell of Example 1 in plan and d represents the electrode pitch.

The interelectrode distance L satisfies the relationship of formula (I) with respect to conductivity σ of the p-type layer 8, thickness t of the p-type layer 8, operation voltage Vₒₚ, operation current Iₒₚ, allowable rate α for interelectrode leak current, length A of one side of a cell in plan, and electrode pitch d:

$$\begin{matrix}[ Math . 1 ] & \\ L \geq \frac{2 σ {tAV}_{op}}{d {I}_{op} α } & ( I )\end{matrix}$$

Accordingly, when σ=1×10⁻⁴ S/cm, t=10 nm, Vₒₚ=0.7 V, Iₒₚ=40 mA/cm², α=0.01, A=10 cm, and d=1 mm, formula (I) finds that the interelectrode distance L needs to satisfy L≧0.35 nm.

The following formula (II) can be derived from formula (I) above.

$$\begin{matrix}[ Math . 2 ] & \\ σ \leq \frac{d {I}_{op} α L}{2 {tAV}_{op}} & ( II )\end{matrix}$$

The formula finds that when L≦1 μm, the conductivity σ of the p-type layer 8 needs to satisfy the relationship σ≦2.8×10⁻¹ S/cm.

### Example 2

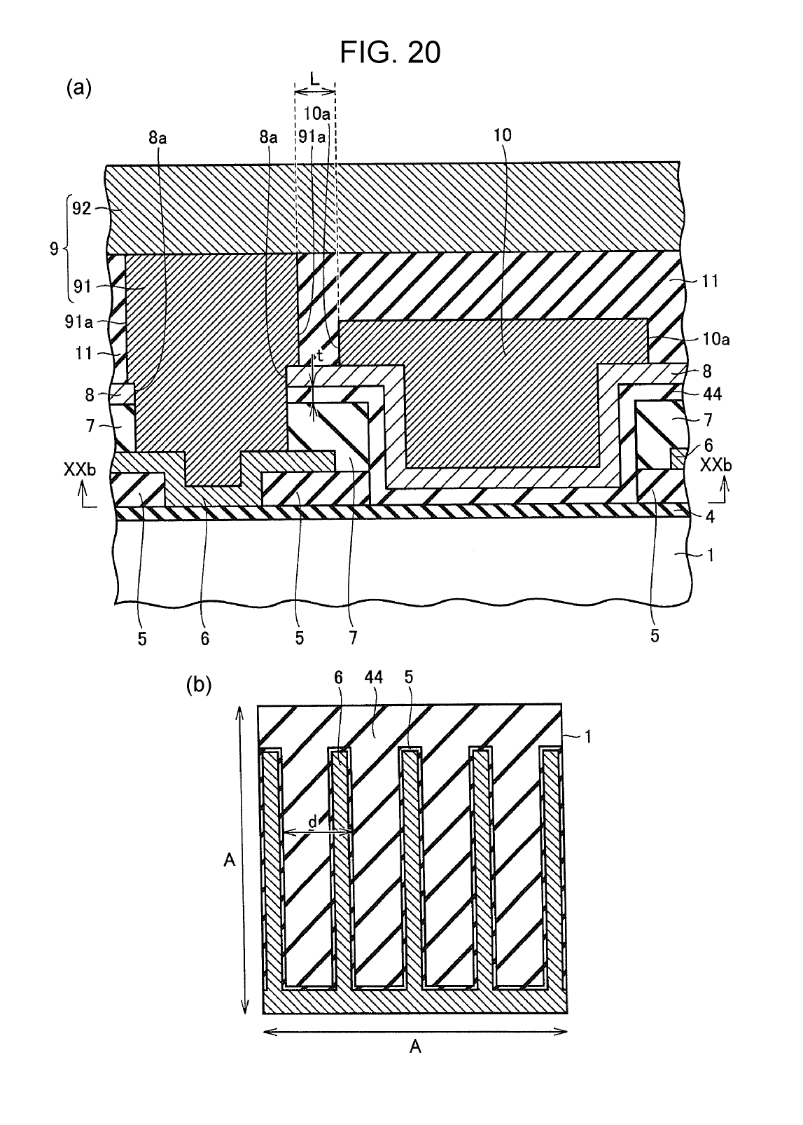

FIG. 20(a) illustrates a cross-sectional structure of a heterojunction-type back-contact cell of Example 2. FIG. 20(b) is a schematic cross-sectional view taken along XXb-XXb in FIG. 20(a). The heterojunction-type back-contact cell of Example 2 differs from the heterojunction-type back-contact cell of Example 1 in that an intrinsic layer 44 containing i-type hydrogenated amorphous silicon is disposed directly below the p-type layer 8.

In the heterojunction-type back-contact cell of Example 2, the thickness of the intrinsic layer directly below the n-type layer 6 and the thickness of the intrinsic layer directly below the p-type layer 8 can be independently controlled. Thus, a heterojunction-type back-contact cell having enhanced properties such as conversion efficiency can be more easily manufactured.

In particular, when the intrinsic layer directly below the n-type layer 6 is thin, the parasitic resistance can be decreased without substantially decreasing the minor carrier lifetime in the intrinsic layer 4. Meanwhile, when the intrinsic layer directly below the p-type layer 8 is thick, the minor carrier lifetime in the intrinsic layer can be increased. Accordingly, properties such as conversion efficiency can be enhanced by making the thickness of the intrinsic layer directly below the p-type layer 8 (in Example 2, the total thickness of the intrinsic layer 4 and the intrinsic layer 44) larger than the thickness of the intrinsic layer directly below the n-type layer 6 (in Example 2, the thickness of the intrinsic layer 4).

### Example 3

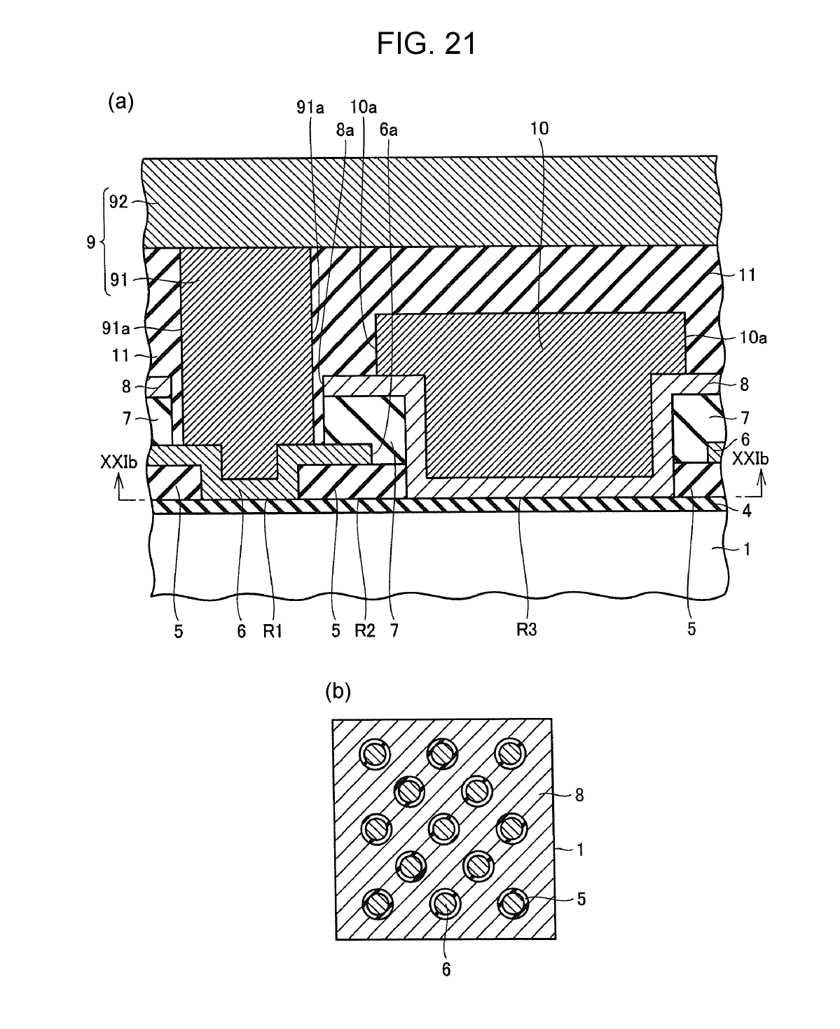

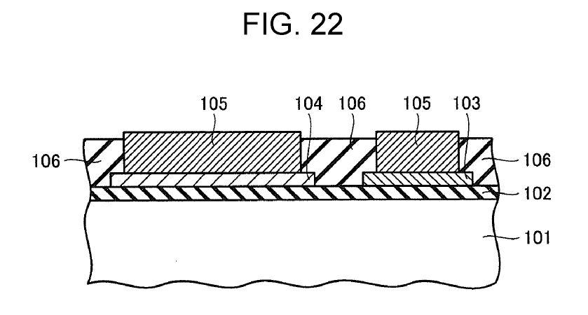

FIG. 21(a) illustrates a cross-sectional structure of a heterojunction-type back-contact cell of Example 3 and FIG. 21(b) is a schematic cross-sectional view taken along XXIb-XXIb in FIG. 21(a). The heterojunction-type back-contact cell of Example 3 differs from the heterojunction-type back-contact cell of Example 1 in that the end portion 9a of the first lower electrode 91 is located on the back surface of the n-type layer 6 and the n-type layer 6 is formed to have a dot pattern.

In the heterojunction-type back-contact cell of Example 3 also, damage on the semiconductor 1 and the intrinsic layer 4 can be decreased, the heterojunction-type back-contact cell can be manufactured in high yield, and properties thereof can be enhanced, as in the cases described above.

### <Overview>

The present invention provides a photoelectric conversion element that includes a semiconductor; an intrinsic layer disposed on the semiconductor and containing hydrogenated amorphous silicon; a first-conductivity-type layer of a first conductivity type that covers a part of the intrinsic layer; a second-conductivity-type layer of a second conductivity type that covers a part of the intrinsic layer; a first insulating layer that covers a part of the intrinsic layer; a first electrode disposed on the first-conductivity-type layer; and a second electrode disposed on the second-conductivity-type layer, in which a part of the first-conductivity-type layer and a part of the second-conductivity-type layer are located above a region where the intrinsic layer contacts the insulating layer. According to this structure, patterning of the first-conductivity-type layer can be conducted over the insulating layer and damage on the semiconductor and the intrinsic layer inflicted during patterning of the first-conductivity-type layer can be decreased. Thus, a photoelectric conversion element can be manufactured in high yield and have enhanced properties.

The present invention also provides a photoelectric conversion element that includes a semiconductor; an intrinsic layer disposed on the semiconductor and containing hydrogenated amorphous silicon; a first-conductivity-type layer of a first conductivity type that covers a part of the intrinsic layer; a second-conductivity-type layer of a second conductivity type that covers a part of the intrinsic layer; a first insulating layer that covers a part of the intrinsic layer; a first electrode disposed on the first-conductivity-type layer; and a second electrode disposed on the second-conductivity-type layer, in which the first electrode includes a first lower electrode in contact with the first-conductivity-type layer and a first upper electrode disposed on the first lower electrode, and a second insulating layer is disposed between the first lower electrode and the second electrode and between the first upper electrode and the second electrode. According to this structure, the photoelectric conversion element can be manufactured in high yield and have enhanced properties.

In the photoelectric conversion element of the present invention, an end portion of the second-conductivity-type layer is preferably located above an end portion of the first-conductivity-type layer with a second insulating layer therebetween. According to this structure, patterning of the second-conductivity-type layer can be conducted over the insulating layer and damage on the semiconductor and the intrinsic layer inflicted during patterning of the second-conductivity-type layer can be decreased. Moreover, since the first-conductivity-type layer and the second-conductivity-type layer are insulated from each other in the thickness direction, the shunt resistance can be significantly increased. Accordingly, the photoelectric conversion element can be manufactured in high yield and have enhanced properties.

In the photoelectric conversion element of the present invention, the first electrode preferably includes a first lower electrode in contact with the first-conductivity-type layer and a first upper electrode disposed on the first lower electrode, and a second insulating layer is preferably disposed between the first lower electrode and the second electrode and between the first upper electrode and the second electrode. According to this structure, since the first upper electrode is disposed on the region between the first lower electrode and the second electrode, the light leaking from the region between the first lower electrode and the second electrode is reflected by the first upper electrode and thus photoelectric conversion losses can be decreased. Moreover, since the first upper electrode is formed above the second electrode, the area of the first upper electrode can be increased and the resistance of the first electrode can be decreased.

In the photoelectric conversion element of the present invention, an end portion of the first lower electrode and an end portion of the second electrode preferably each have a part located above the second insulating layer. According to this structure, patterning of the first lower electrode and the second electrode can be conducted over the second insulating layer and thus damage on the semiconductor, the intrinsic layer, and the first-conductivity-type layer by patterning can be prevented.

In the photoelectric conversion element of the present invention, the second-conductivity-type layer preferably has a conductivity of 0.28 S/cm or less. According to this structure, the interelectrode distance between the first lower electrode and the second electrode can be decreased to 10 μm or less. Thus, the amount of light passing through the gap between the first lower electrode and the second electrode can be decreased, the amount of light reflected toward the semiconductor side can be increased, and thus the properties of the photoelectric conversion element can be improved.

In the photoelectric conversion element of the present invention, the second conductivity type is preferably a p-type. As a result, a satisfactory passivation effect can be obtained at a surface of the semiconductor by the intrinsic layer.

In the photoelectric conversion element of the present invention, the thickness of the intrinsic layer in a region that contacts the second-conductivity-type layer is preferably larger than the thickness of the intrinsic layer in a region that contacts the first-conductivity-type layer. According to this structure, a satisfactory passivation effect can be obtained at a surface of the semiconductor by the intrinsic layer.

While embodiments and examples of the present invention have been described above, appropriately combining the features of the embodiments and examples described above is also anticipated from the beginning.

The embodiments and examples disclosed herein are merely illustrative in all aspects and should not be considered as limiting. The scope of the present invention is to be defined not by the description above but by the claims and is intended to cover all modifications within the scope of the claims and equivalents thereof.

### INDUSTRIAL APPLICABILITY

The present invention is applicable to photoelectric conversion elements and methods for manufacturing photoelectric conversion elements, in particular, to a heterojunction-type back-contact cell and a method for manufacturing a heterojunction-type back-contact cell.

### REFERENCE SIGNS LIST

1 semiconductor
2 texture structure
3 antireflection film
4 intrinsic layer
5 first insulating layer
6 n-type layer
6a end portion
6b groove portion
6c flap portion
7 second insulating layer
8 p-type layer
8a end portion
8b groove portion
8c flap portion
9 first electrode
10 second electrode
10a end portion
11 third insulating layer
21 resist
22 opening
31 resist
32 opening
41 resist
42 opening
44 intrinsic layer
51 resist
52 opening
61 resist
62 opening
71 resist
72 opening
91 first lower electrode
91a end portion
92 first upper electrode
101 crystalline silicon wafer
102 hydrogenated amorphous silicon transition layer
103 n-doped region
104 p-doped region
105 electrode
106 reflecting layer
1000 photoelectric conversion module
1001 photoelectric conversion element
1002 cover
1013, 1014 output terminal
2000 solar power generation system
2001 photoelectric conversion module array
2002 junction box
2003 power conditioner
2004 distribution board
2005 power meter
2011 electrical appliance
2013, 2014 output terminal
3000 module system
3002 junction box
3004 collecting box
4000 solar power generation system
4001 subsystem
4003 power conditioner
4004 transformer

1. A photoelectric conversion element comprising:
a semiconductor;
an intrinsic layer disposed on the semiconductor and containing hydrogenated amorphous silicon;
a first-conductivity-type layer of a first conductivity type that covers a part of the intrinsic layer;
a second-conductivity-type layer of a second conductivity type that covers a part of the intrinsic layer;
a first insulating layer that covers a part of the intrinsic layer;
a first electrode disposed on the first-conductivity-type layer; and
a second electrode disposed on the second-conductivity-type layer,
wherein a part of the first-conductivity-type layer and a part of the second-conductivity-type layer are located above a region where the first intrinsic layer contacts the insulating layer.

2. The photoelectric conversion element according to claim 1, wherein an end portion of the second-conductivity-type layer is located above an end portion of the first-conductivity-type layer with a second insulating layer therebetween.

3. The photoelectric conversion element according to claim 1, wherein the first electrode includes a first lower electrode in contact with the first-conductivity-type layer and a first upper electrode disposed on the first lower electrode, and
a third insulating layer is disposed between the first lower electrode and the second electrode and between the first upper electrode and the second electrode.

4. The photoelectric conversion element according to claim 2, wherein an end portion of the first lower electrode and an end portion of the second electrode each have a part located above the second insulating layer.

5. The photoelectric conversion element according to claim 1, wherein the second conductivity type is a p-type.
